(19) United States
(12) Patent Application Publication
(10) Pub. No.: US 2004/0144107 A1
(43) Pub. Date: Jul. 29, 2004

(54) HVAC controls for a vehicle with start-stop engine operation

(76) Inventors: Matthew Breton, Westland, MI (US); Peter Rex Gawthrop, Royal Oak, MI (US); Kanwal Bhatia, Troy, MI (US)

Correspondence Address: VISTEON, C/O BRINKS HOFER GILSON & LIONE, PO BOX 10395, CHICAGO, IL, 60610, US

(21) Appl. No.: 10/351,937

(22) Filed: Jan. 27, 2003

(51) Int. Cl. G01K 13/00; B60H 1/32; H02N 2/00; H01L 41/04; H01L 41/08; H01L 41/18

(52) U.S. Cl. 62/129; 62/133

(57) ABSTRACT

A system and method for determining engine operation for a start-stop vehicle is provided. The start-stop vehicle includes an HVAC system. The engine operation control system includes an HVAC control head for indicating demand, a sensor for indicating fan speed, at least one sensor for indicating ambient air temperature, and a powertrain control module in communication with the HVAC control head and the sensors. The powertrain control module determines engine operation. The method for controlling engine operation includes the steps of determining HVAC demand, fan speed, and ambient temperature to a control module. The control module determines engine operation based on the signals from the signal generators of the HVAC demand, the fan speed, and the ambient temperature.

### FIELD OF THE INVENTION

The present invention relates to vehicles with start-stop engine operation. In particular, the present invention as disclosed herein relates to a heating, ventilation, and air conditioning control system for a vehicle with start-stop engine operation.

### BACKGROUND OF THE INVENTION

In a conventional vehicle, the engine is responsible for providing a number of key elements of a heating, ventilation, and air conditioning (HVAC) system. Heat is transferred into the passenger compartment via the engine coolant and a heater core. The conventional engine also provides the power for an air conditioning compressor to maintain the temperature of the air conditioning core.

Start-stop vehicles, also known as idle stop or hybrid vehicles, have the capability to stop the engine when the vehicle is not moving to reduce fuel consumption and greenhouse emissions. In some driving situations, the start-stop vehicle engine may be turned off for long periods of time and over a large percentage of the driving cycle. Because the engine is not run constantly, heat from the heater core and the air conditioning compressor cannot be relied upon to heat and cool the passenger cabin as in the conventional vehicle. Modifications must be made to the start-stop vehicle engine operation control system to provide heating, ventilation, and air conditioning for passenger comfort when the vehicle is stopped and the start-stop engine is turned off.

Current HVAC and engine control systems in start-stop vehicles use separate electronic climate control modules to determine whether or not the engine can be turned off or must be turned back on. Other HVAC systems use auxiliary electric heaters to provide cabin heat when the engine is off, or an electric motor is used to drive the air conditioning compressor. These systems add cost and complexity to a vehicle and additionally require the passengers to become familiar with a new system for the vehicle. A simple on-off strategy has also been used to prevent the engine from shutting off when air conditioning is requested by the user, but some of the fuel economy is lost by requiring the engine to be on for all air conditioning requests.

Therefore, a need exists for a start-stop vehicle engine control system that provides improved fuel economy over a simple switched system, is cost effective, and is easy for the passenger to use.

### BRIEF SUMMARY OF THE INVENTION

In order to alleviate one or more shortcomings of the prior art, a control system and method are provided herein. In accordance with the present invention, a control system and method are disclosed herein for engine operation of a start-stop vehicle having an HVAC system.

In one aspect of the present invention, a system for controlling a start-stop vehicle engine having an HVAC system is provided. The system comprises an HVAC control head for indicating demand, a sensor for indicating fan speed, at least one sensor for indicating ambient air temperature, and a powertrain control module in communication with the HVAC control head and the sensors. The powertrain control module determines engine operation.

In another aspect of the present invention, a method for controlling a start-stop engine having an HVAC system is provided. The method includes the steps of determining HVAC demand, fan speed and ambient temperature and providing this information to a control module. The control module determines engine operation based on the HVAC demand, the fan speed, and the ambient temperature.

Advantages of the present invention will become more apparent to those skilled in the art from the following description of the preferred embodiments of the invention that have been shown and described by way of illustration. As will be realized, the invention is capable of other and different embodiments, and its details are capable of modification in various respects.

Accordingly, the drawings and description are to be regarded as illustrative in nature and not as restrictive.

### BRIEF DESCRIPTION OF SEVERAL VIEWS OF THE DRAWINGS

FIG. 1 is a schematic diagram illustrating the relevant parts of an HVAC control system that may be used to implement the present embodiment of the invention;

FIG. 2 is a logic flow diagram illustrating a preferred embodiment of a control scheme for a start-stop engine control system in accordance with another embodiment of the present invention;

FIG. 3A is a schematic diagram of a portion of an electrical circuit for a preferred embodiment of the present invention;

FIG. 3B is a continuation of the schematic diagram of a portion of an electrical circuit for a preferred embodiment of the present invention; and

FIG. 4 is a pictorial diagram illustrating an HVAC climate control head in accordance with an embodiment of the present invention.

### DETAILED DESCRIPTION OF THE INVENTION

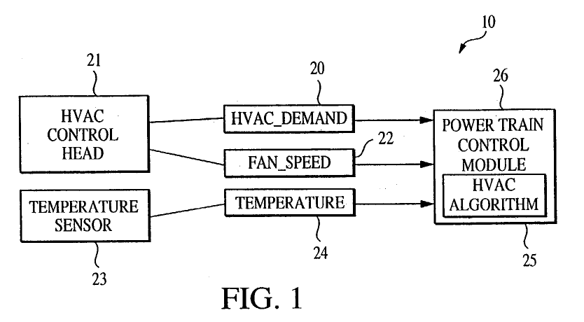

An exemplary engine operation control system using the HVAC system that can be implemented in the present embodiment of the invention is shown in the schematic diagram of FIG. 1. The start-stop engine control system 10, as shown in this embodiment, comprises three signal generators: a signal generator for HVAC demand 20, a signal generator for fan speed 22 and a signal generator for temperature 24, transmitting signals to an HVAC algorithm block 25 within a powertrain control module 26. The HVAC demand signal generator 20 indicates the HVAC operating mode selected by the operator at the HVAC control head 21. The fan speed signal generator 22 indicates HVAC fan speed selected by the operator at the HVAC control head 21. The fan speed signal generator 22 indicates whether the HVAC system is on or off and the speed at which the fan is running, both of which are indications of user demand that may be determined by methods known in the art. The temperature signal generator 24 indicates ambient air temperature either by direct measurement using a temperature sensor 23 or more preferably by inferring ambient air temperature based on signals transmitted from other sensors (not shown) such as an air charge temperature sensor or an engine coolant temperature sensor. Any temperature sensor or combination of temperature sensors, commonly known in the art, may be used to detect the ambient air temperature and transmit a signal indicating the ambient air temperature via the temperature signal generator 24 to the HVAC algorithm block 25. The temperature signal generator 24 continually indicates ambient temperature to the HVAC algorithm block 25. It should be noted that a variety of sensors or other detectors may be used to generally sense various vehicle conditions that might be relevant to determining engine operation as is best to effect HVAC operation. Such sensors can be located to sense temperatures either outside or inside the vehicle.

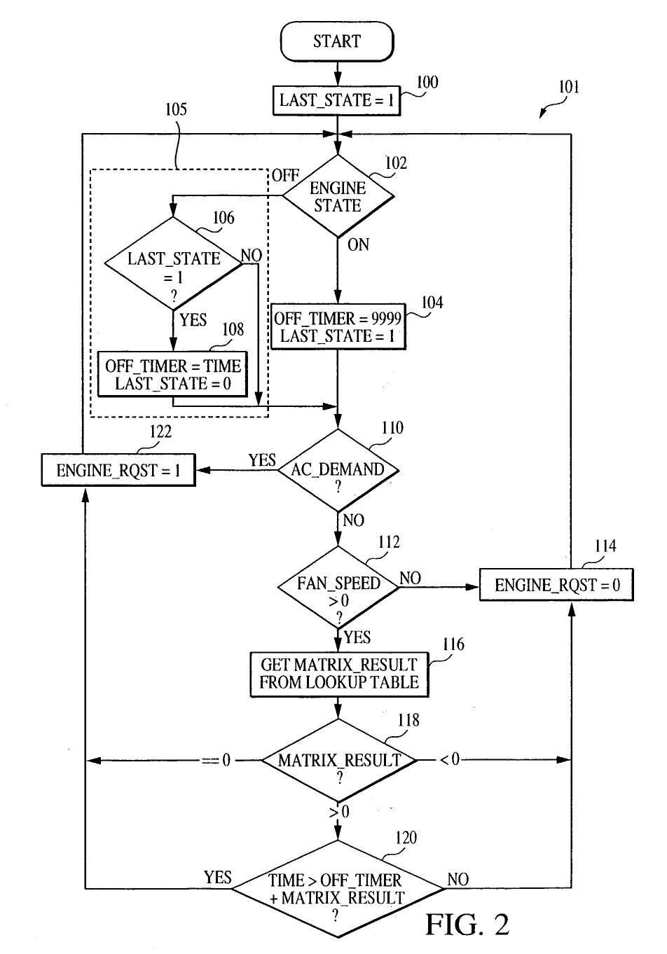

The powertrain control module 26 uses the HVAC algorithm output (described below, FIG. 2), to effect engine operation based on the signals transmitted from the HVAC demand signal generator 20, the fan speed signal generator 22, and the temperature signal generator 24. The control module 26 may contain the supervisory controls and the engine controls within the powertrain control module 26. Alternatively, the powertrain control module 26 may contain the supervisory controls and in turn, transmit signal to an engine control unit (not shown). In one embodiment, engine operation is effected using the engine control unit. Alternatively, the powertrain control module 26 may transmit signals to a powertrain supervisory controller. Any engine controller, commonly known in the art, may be adapted to receive signals transmitted from the control module 26.

The start-stop vehicle engine, as described in the present embodiment, typically operates in three modes. In a first mode, the engine is always on. This “always on” mode of engine operation requires the engine to be on about 100% of the time the vehicle is in operation for heating or cooling purposes, regardless of whether the vehicle is stopped.

In a second mode, the engine operates in an “always off” mode. In this mode, the heating and cooling demands do not require engine operation in order to be met. Provided that no other system requires engine operation, the engine is off when the vehicle is stopped.

In a third mode for engine operation, the mode is “timed off”. The “timed off” mode of engine operation consists of operation of the engine in accordance with a logic matrix that is responsible for determining how long the engine is allowed to stay off when the start-stop vehicle is stopped, while still allowing for engine operation sufficient to meet the comfort requirements of the passenger. The “timed off” mode operates when the HVAC demand signal generator 20 does not signal to the powertrain control module 26 to operate in the engine “always on” or “always off” mode. An exemplary matrix table (shown below, Table 1) determines the length of time that the “timed off” mode operates based on fan speed signal generator 22 input and temperature signal generator 24 input. If the time the engine is off, when the vehicle is stopped, exceeds the “timed off” mode time limit, the powertrain control module 26 transmits a signal to turn on the engine. The control module 26 may effect engine operation or, alternatively control module 26 may transmit a signal to the engine control unit to turn on the engine.

A preferred implementation of the controller steps performed by the HVAC algorithm 25 in the powertrain control module 26 is shown in the logic flow chart diagramed in FIG. 2.

In order to initialize the HVAC algorithm in the powertrain control module, the engine must have previously been turned on. After the initial engine state is determined at 100, the HVAC algorithm continually runs through a logic loop 101 to monitor input changes by the operator. By continually cycling through the logic loop 101, the HVAC algorithm can signal to the powertrain control module to immediately change the engine operation mode if necessary, in response to the operator selection, at the time the operator enacts the change.

In the algorithm, an engine state is determined at 102. If the engine state is on, a calibration value for time is assigned at 104. In the preferred embodiment shown in FIG. 2, a value of 9999 is assigned, representing that when the engine is on, an infinite time may elapse before the “timed off” mode time limit is exceeded. A value of 9999 is assigned when the engine is on, represented by output=1. The algorithm continues from calibration time at 104 to an AC demand input at 110. Of course, other values may be assigned to represent when the engine is on.

If the engine state at 102 is off, a separate loop at 105 is used to detect the transition from the engine on mode to the engine off mode to determine the length of time the engine has been off. An engine state determination at 106 considers whether the previous engine state was engine on mode. If the previous engine state was the engine on mode, a time value is set at 108, indicating the time when the engine was turned off. The set time is determined from any timer within the powertrain control module, which is a determination known in the art. Alternatively, a separate timer for the HVAC algorithm may be used and time value set at 108 may be reset to zero. The set time value will be used, as described below, to determine if the engine “timed off” mode time limit has been exceeded. The algorithm continues to the AC demand input at 110. If the engine state determination at 106 determines that the previous engine state was not in the engine on mode, indicating that the engine has been off for more than one logic cycle, a time is not set and the algorithm continues to the AC demand input at 110, bypassing the time value set at 108.

The logic determinations at steps 104, 106, and 108 all proceed to step 110. The AC demand input at 110 is determined using input from the HVAC selector signal generator as discussed below. If the input from AC demand input at 110 indicates that there is no requirement for the engine “always on” mode of operation, a fan speed at 112 is determined. When the fan speed at 112 is not greater than zero, an engine request logic at 114 outputs a “0”, signaling engine “always off” mode of operation. The algorithm returns to the determination of the engine state at 102.

When the fan speed at 112 is greater than zero, this indicates that the HVAC system is in demand by the passenger. A matrix table at 116 supplies a result at 118, in this case. A sample strategy matrix is described below and shown in Table 1. Any sample matrix may be used to supply a result at 118. If the matrix result at 118 is less than zero, the engine request logic at 114 outputs a “0”, signaling engine “always off” mode of operation. The algorithm logic returns to the engine state inquiry at 102.

If the matrix result at 118 is greater than zero, a time determination at 120 is made by comparing the set time value at 108 with the “timed off” time limit from the matrix table at Table 1, for example. If the set time value at 108 is greater than the time allowed by the matrix table at 116, compared in the time at 120, the engine request logic at 122 outputs a “1”, signaling the engine “always on” mode of operation. The algorithm returns to the engine state inquiry at 102.

If the set time value at 108 is not greater than the “timed off” cycle, the engine request logic at 114 outputs a zero, signaling the engine “always off” mode of operation. The algorithm returns to the engine state inquiry at 102. When the matrix result at 118 equals zero, the engine request logic at 122 outputs a “1”, signaling the engine “always on” mode of operation, and the algorithm returns to the engine state inquiry at 102.

When the AC demand at 110 indicates input from a selection indicator that requires engine “always on” mode, the engine request at 122 outputs a “1”, indicating the engine “always on” mode of operation and a signal is transmitted to the powertrain control module. The algorithm returns to the engine state inquiry at 102.

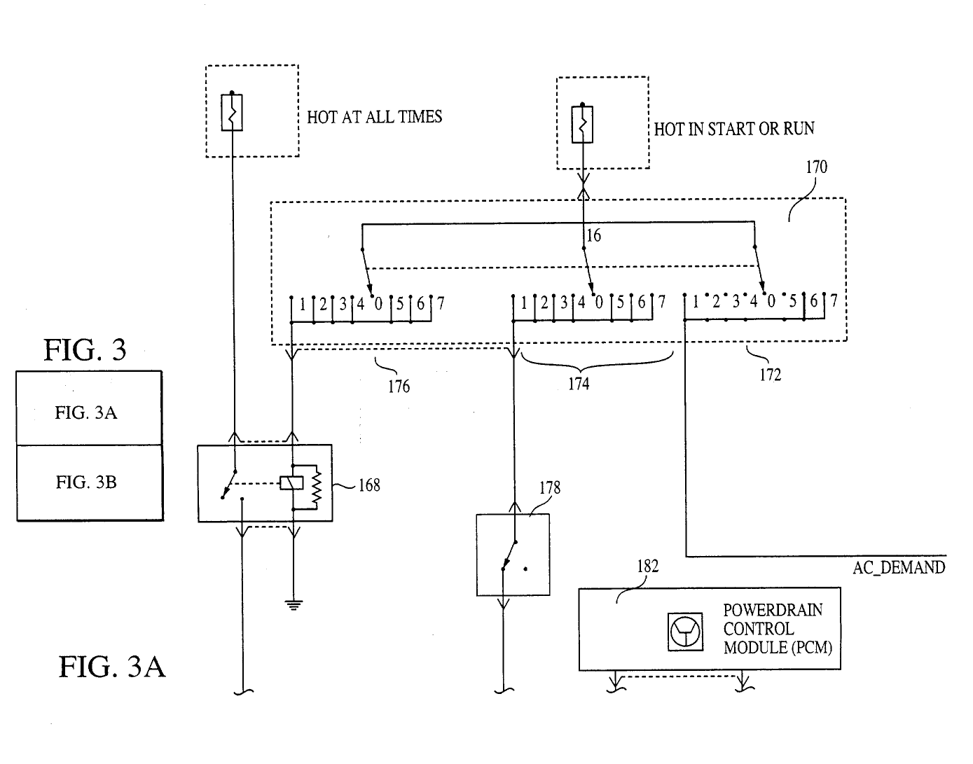

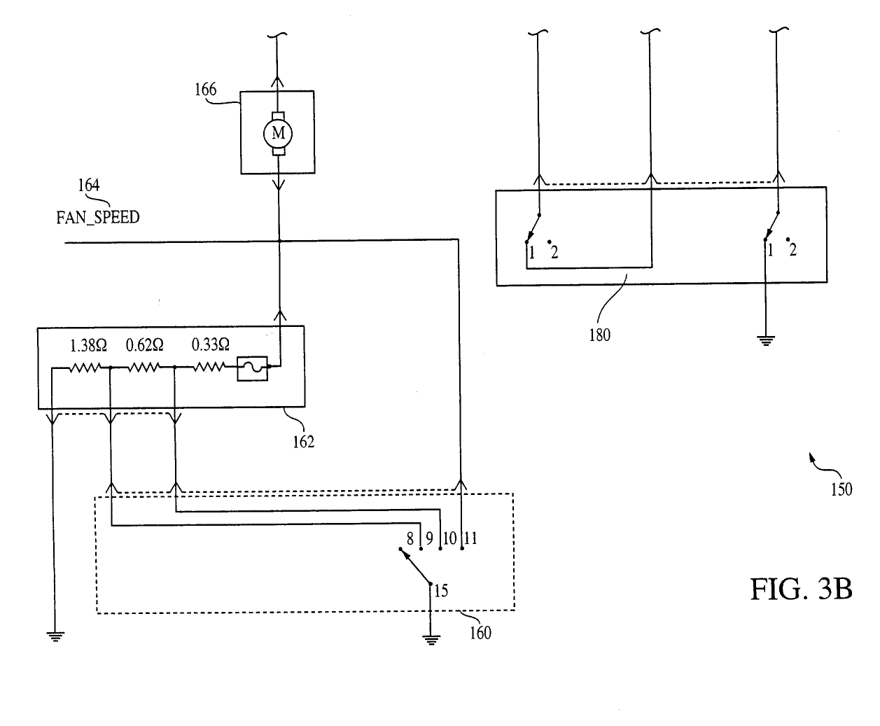

In another embodiment of the present invention, the input signal from the electronic circuits use AC_Request and Fan_Speed input, but a separate circuit, as shown in FIG. 3 for AC_Demand, is not included. The controller steps performed by the HVAC algorithm in the embodiment without the AC_Demand input eliminate the input determination at step 110 of FIG. 2. The algorithm does not proceed to the engine “always on” output at step 120, instead, the algorithm proceeds to Fan_Speed input at 114 and the matrix table look up at 116 to determine either “engine off” mode or “engine timed off”mode. The algorithm shown in FIG. 2 proceeds from step 104, 106, or 108 to step 112, eliminating step 110 in this embodiment.

FIGS. 3A and 3B are a block diagram illustrating a schematic circuit implementing a preferred embodiment of the present invention. FIGS. 3A and 3B together illustrate the preferred electrical circuit 150 for determining input signals for fan speed and AC demand for the logic algorithm shown in FIG. 2.

The electrical circuit 150 comprises a fan speed switch assembly 160 operably connected to a blower motor resistor assembly 162 and a fan_speed signal generator 164. The fan_speed signal generator 164 is placed between the fan speed switch assembly 160 and a blower motor 166 to provide the powertrain control module 26 with an analog signal indicative of fan speed based on the voltage across the blower motor resistor assembly 162. The fan speed switch assembly 160 may include positions for low, medium 1, medium 2, and high. Alternatively, the fan speed switch assembly 160 may include a position for off.

The blower motor 166 is operably connected to a blower motor relay 168 and the motor relay 168 is connected to a function selector switch assembly 170 for HVAC selection. The switch assembly 170 comprises three switches. The switch 172 indicates AC_Demand input for the logic algorithm, based on the position of a control head, the position being selected by the operator, indicating an engine “always on” mode of operation when selections for maximum air conditioning, defrost, floor air flow, and defrost are selected. The switch 172 may include positions for off, max, normal, vent, floor/vent, floor, mix, and defrost. An AC_Request switch 174 provides input to the logic algorithm of the powertrain control module 182 when the AC_Demand switch 172 does not indicate engine “always on” mode of operation. The switch 174 operably connects to an AC clutch cycling pressure switch 178 that transmits signal to a dual pressure switch 180. The dual pressure switch 180 signals to the powertrain control module 182 whether sufficient pressure exists to effect engine operation to meet the AC_Request signaled by switch 174. A blower switch 176 signals through the blower motor relay 168 to the blower motor 166 to indicate the fan speed 164 for input into the logic algorithm. The fan speed 164 inputs signals into the logic algorithm from the fan speed switch assembly 160 and the blower switch 176.

In another embodiment of the preset invention, the function selector switch described in FIG. 3, may comprise an AC_Request switch and a blower switch. The input signals transmitted to the logic algorithm are described above.

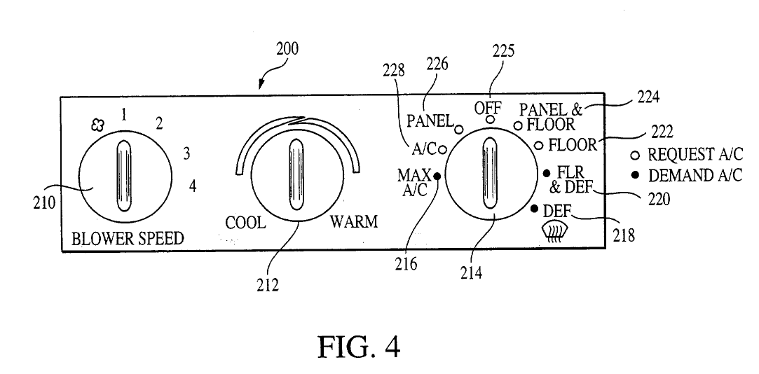

FIG. 4 is a pictorial diagram illustrating an HVAC climate control head 200 of an exemplary embodiment of the invention. The control head 200 operably connects to the HVAC algorithm block 25 in the powertrain control module 26 (shown in FIG. 1). The HVAC climate control head 200 includes illustrated indicia showing the various modes of operation. The control head shown in FIG. 4 comprises a collection of controls, including a blower speed control 210, a temperature control 212 and an air outlet selection control 214, each of which is depicted as a rotary knob. Selection for each of the controls requires the user to rotate the rotary knob to choose among the modes of operation, and the selection causes an appropriate signal to be sent to either the powertrain control module 26 or any other relevant system in the automobile.

A generally conventional air outlet selection control 214 causes a signal input into the HVAC algorithm block in the powertrain control module (shown in FIG. 1). The selection control 214, as illustrated in FIG. 4, shows a preferred embodiment for the selection options available to the user. The selection options shown in this embodiment are maximum air conditioning, MAX A/C 216, defrost, DEF 218, floor air flow and defrost, FLR & DEF 220, floor air flow, FLOOR 222, floor and panel air flow, PANEL & FLOOR 224, no air flow, OFF 225, panel air flow, PANEL 226, and air conditioning, A/C 228. Other configurations are, of course, possible.

Using the algorithm of the preferred embodiment, the engine “always on” mode of operation is determined and is activated by the HVAC 30 demand input from the control head. For example, when the control 214 is used to select modes of operation at the positions MAX/AC 216, DEF 218, and FLR&DEF 220, the HVAC algorithm in the powertrain control module transmits an appropriate signal to the engine control unit to demand the engine to operate in the “always on” mode.

The “timed off” mode is activated by the HVAC demand input from the control head and by the fan speed and temperature signal generators as discussed above. For example, when the operator uses the control 64 to select the position FLOOR 222, PANEL & FLOOR 224, PANEL 226, or A/C 228, the logic algorithm, in the powertrain control module, will use the exemplary matrix table of Table 1 to determine the length of time for the “timed off” mode to operate. The powertrain control module transmits a signal to the engine control unit to request the engine be turned on if the “timed off” time limit determined by the matrix table has been exceeded.

The “always off” mode is activated when the fan speed is zero. Fan speed is zero when the selection control 214 is rotated to OFF 225, indicating that the HVAC system is off. In a preferred embodiment, as shown in FIG. 4, the blower speed control 210 allows user input for fan speed and the fan is always running at some speed unless the selection control 214 is rotated to OFF 225. The “always off” mode is also activated by combinations of fan speed and temperature determined by the exemplary matrix table of the logic algorithm block 25 in the powertrain control module 26. In the “always off” mode, no signal is transmitted from the powertrain control module 26 to effect engine operation.

In another embodiment of the present invention, the blower speed control allows the user to select “fan speed off” on the blower speed control as well as on the selection control. The selection control may still indicate a demand of the HVAC system when the blower speed is off and the selection control is in any position except off. The logic algorithm will not allow the command to start the engine “always off” mode of operation if the selection control indicates a demand even though the blower speed is off. The algorithm will determine the engine operation in the “timed off” mode.

TABLE 1
SAMPLE STRATEGY MATRIX

| Ambient | | | | | |
|---|---|---|---|---|---|
| Temp | | | | | |
| (T_{A}) | | | | | |
| (° C.) | Off | Low | Medium 1 | Medium 2 | High |
| −40 | ALWAYS_OFF | ALWAYS_ON | ALWAYS_ON | ALWAYS_ON | ALWAYS_ON |
| −35 | ALWAYS_OFF | ALWAYS_ON | ALWAYS_ON | ALWAYS_ON | ALWAYS_ON |
| −30 | ALWAYS_OFF | ALWAYS_ON | ALWAYS_ON | ALWAYS_ON | ALWAYS_ON |
| −25 | ALWAYS_OFF | ALWAYS_ON | ALWAYS_ON | ALWAYS_ON | ALWAYS_ON |
| −20 | ALWAYS_OFF | ALWAYS_ON | ALWAYS_ON | ALWAYS_ON | ALWAYS_ON |
| −15 | ALWAYS_OFF | 120 | ALWAYS_ON | ALWAYS_ON | ALWAYS_ON |
| −10 | ALWAYS_OFF | 132 | ALWAYS_ON | ALWAYS_ON | ALWAYS_ON |
| −5 | ALWAYS_OFF | 144 | 84 | ALWAYS_ON | ALWAYS_ON |
| 0 | ALWAYS_OFF | 156 | 96 | ALWAYS_ON | ALWAYS_ON |
| 5 | ALWAYS_OFF | 168 | 108 | ALWAYS_ON | ALWAYS_ON |
| 10 | ALWAYS_OFF | 180 | 120 | ALWAYS_ON | ALWAYS_ON |
| 15 | ALWAYS_OFF | 192 | 132 | 108 | ALWAYS_ON |
| 20 | ALWAYS_OFF | 180 | 144 | 120 | ALWAYS_ON |
| 25 | ALWAYS_OFF | 120 | 156 | 108 | 108 |
| 30 | ALWAYS_OFF | 30 | 144 | 60 | 60 |
| 35 | ALWAYS_OFF | 18 | ALWAYS_ON | ALWAYS_ON | ALWAYS_ON |
| 40 | ALWAYS_OFF | ALWAYS_ON | ALWAYS_ON | ALWAYS_ON | ALWAYS_ON |

A sample strategy matrix for the HVAC algorithm is shown in Table 1, for a preferred embodiment of the present invention. Simulation was used to develop a range of conditions when the operator would not be adverse to the engine shutting down. Additional studies were conducted to determine how long the blower could remain running with the engine off before the operator would notice a loss in comfort. The results for the simulation studies were fed into a matrix to generate Table 1. Table 1 provides a sample strategy matrix for the logic algorithm at step 116 in FIG. 2, and shows ambient temperature in ° C. as a function of fan speed. As described above, temperature is ambient temperature indicated by a sensor and fan speed is determined from input from the HVAC selector and the blower speed selector. As shown in the column indicating fan speed off, the matrix table provides a signal indicating engine always off mode, at every temperature, based on the operator selection. For fan speeds Low, Medium 1, Medium 2, and High, the engine operation mode in the matrix changes based on the ambient temperature. The values indicated in the matrix indicate time, in seconds, that the engine may operate in the timed off mode. The time limit for the timed off mode is supplied to the HVAC algorithm in the Matrix_result inquiry described at step 118 in FIG. 2. Output to the logic algorithm from the matrix table signals—1 for ALWAYS_OFF and 0 for ALWAYS_ON.

In another embodiment of the present invention, a logic algorithm for determining a minimum time for engine off and engine on modes of operation may be used to prevent rapid on/off cycling of the engine.

The engine on/off algorithm determines an engine state. When the engine is off, a time demand for the logic and the engine state are set to off. If the engine state is greater than zero, indicating the engine has been turned on, the time demand and the engine state are set to on, and a time when the engine turned on is recorded. The timer may be any timer present in the powertrain control module. When the time demand and the engine state are requested to be set to engine off, the logic determines if the time for the engine off request is greater than the time elapsed when a time was entered when the engine was turned on plus a minimum time for the engine to be on. The minimum time for the engine to be on is about 120 seconds. A minimum time requirement for the engine to operate in the on mode is also based on emissions controls for a vehicle, occupant comfort due to HVAC constraints, battery charge constraints, and the need to avoid the rapid cycling of the engine between the on and the off modes for durability and minimizing customer perception of the operation.

In another embodiment of the present invention, an air conditioning logic algorithm may be used with the HVAC logic algorithm to determine a minimum time for engine on/ off cycling based on a time determination of how long an HVAC air conditioning system has been running. A minimum time may be regulated by the AC logic based on an algorithm that determines the length of time the air conditioning system has been running and whether a minimum time determination has been met to allow the air conditioning system to build up pressure in the system and to cool down an exchanger for air cooling. If the time determined for air conditioning on exceeds the minimum time requirement, the powertrain control module may transmit signal to the engine control unit to turn the engine off. The time required to perform initial cabin cool-down of a vehicle interior is typically in the range of 180 to 360 seconds.

In another embodiment of the present invention, a water pump may be added to the coolant system. The water pump is any pump commonly known in the art. Addition of the water pump allows circulation of water through the heater core of the HVAC system, thus retarding the cooling down of the HVAC system and thereby extending the timed off time limit for engine operation in cold weather. The water pump extends the length of the engine timed off mode when the engine is operating under cold weather conditions, in the range from about 10° C. to about −40° C. The HVAC logic algorithm diagramed in FIG. 2 may be used with the water pump embodiment. The matrix strategy table would use a different set of numbers than the timed off determinations in Table 1, however, the set of numbers would be generated under the simulation conditions used for generating Table I, and adding a water pump to the test system.

In another embodiment of the present invention, the control system for engine operation may be used for a start-stop vehicle having more than one climate zone. A multiple climate zone vehicle, such as a minivan, may have a control head for each zone. An HVAC control system for a vehicle with multiple climate zones includes a signal transmission from each control head to a logic algorithm. In one embodiment of the present invention, the multiple climate zone vehicle logic algorithm has two matrix tables to supply values for determining the engine mode of operation.

An additional step in the algorithm compares the values from the two tables and selects the shorter time limit for the timed off engine operation for the logic algorithm to determine output from the algorithm to the powertrain control module. Other configurations are possible for selecting which control head will determine the time limit for the engine timed off mode. For example, it is possible to select one control head to be the master and thus the signal from the master control head determines the time limit for the engine timed off or engine always on or engine always off modes of operation.

While preferred embodiments of the invention have been described, it should be understood that the invention is not so limited and modifications may be made without departing from the invention. The scope of the invention is defined by the appended claims, and all devices that come within the meaning of the claims, either literally or by equivalence, are intended to be embraced therein.

1. A control system for a start-stop vehicle engine having an HVAC system, said control system comprising:
a powertrain control module;
a signal generator, in communication with said powertrain control module, for indicating demand from an HVAC control;
a signal generator, in communication with said powertrain control module, for indicating fan speed;
a signal generator, in communication with said powertrain control module, for indicating ambient air temperature; and
wherein said control module operably connected to said HVAC control signal generator, said fan speed signal generator, and said temperature sensor signal generator, wherein said control module determines engine operation based on information from said signal generators.

2. The control system of claim 1 further comprising an engine control unit operably connected to said control module.

3. The control system of claim 1 wherein said control module further stores and runs at least one algorithm for determining a mode of engine operation.

4. The control system of claim 3 wherein said at least one algorithm further determines a mode of engine operation, said mode of engine operation selected from engine always on, engine always off, and engine timed off.

5. The control system of claim 4 wherein said algorithm for determining said mode of engine operation for engine timed off further comprises a matrix table for determining a time limit for engine timed off operation.

6. The control system of claim 1 wherein said control module further stores and runs at least one algorithm for determining an engine state wherein said at least one algorithm determines a minimum time for said engine to operate to prevent rapid on/off cycling of said engine.

7. The control system of claim 1 wherein said control module further stores and runs at least one algorithm for determining a minimum time for an air conditioner to run before said control module effects engine operation to turn off said engine.

8. The control system of claim 1 wherein said HVAC control further comprises at least two or more control panels to determine engine operation.

9. The control system of claim 4 wherein said start-stop vehicle further comprises an electric water pump to extend the time limit for said engine off mode of operation in cold weather.

10. A method for controlling engine operation of a start-stop vehicle having an HVAC system, said HVAC system comprising an HVAC control for indicating demand, a fan, an air conditioning unit, a heating unit, a temperature sensor, a powertrain control module, and an engine control unit, said method comprising the steps of:
determining HVAC demand from said HVAC control and providing a signal indicative thereof to said control module;
determining fan speed of said fan and providing a signal indicative thereof to said control module;
determining ambient air temperature from said temperature sensor and providing a signal indicative thereof to said control module;
generating an engine control signal in said control module based on information indicative of HVAC demand, fan speed and temperature, and sending the engine control signal to said engine control unit to effect operation.

11. The method of claim 10 wherein determining whether said control module should effect engine operation further comprises the step of determining a mode of engine operation using at least one algorithm.

12. The method of claim 11 wherein said at least one algorithm determines said mode of engine operation by selecting from engine always on mode, engine always off mode, and engine timed off mode.

13. The method of claim 12 wherein determining said mode of engine operation for engine timed off mode using said algorithm further comprises the step of using a matrix table for determining a time limit for said engine timed off mode of operation.

14. The method of claim 11 wherein said at least one algorithm further comprises the step of determining a minimum time for the engine to operate in a mode of operation to prevent rapid on/off cycling.

15. The method of claim 11 wherein said at least one algorithm further comprises the step of determining a minimum time for an air conditioner to run before said control module effects engine operation to turn off said engine.

16. The method of claim 10 wherein said step of determining HVAC control demand further comprises determining HVAC demand from at least two or more control panels and providing a signal indicative thereof to said control module to effect engine operation.

17. The method of claim 13 wherein the step of determining said timed off mode further comprises a matrix table for use when said start-stop vehicle further comprises an electric water pump to extend the time limit for said engine off mode of operation in cold weather.

18. An engine operation control system for a start-stop vehicle having an HVAC system, said HVAC system comprising an HVAC control for indicating demand, a fan, an air conditioning unit, a heating unit, a temperature sensor, a powertrain control module, and an engine control unit, said system comprising:
means for determining HVAC demand and providing a signal indicative thereof;
means for determining fan speed and providing a signal indicative thereof;
means for determining ambient air temperature and providing a signal indicative thereof; and
means in communication with said means for determining HVAC demand, means for determining fan speed, and means for determining ambient air temperature, for generating an engine control signal in said control module based on information indicative of HVAC demand, fan speed and temperature, and sending the engine control signal to said engine control unit to effect operation.
